(19) United States
(12) Patent Application Publication
(10) Pub. No.: US 2002/0003308 A1
(43) Pub. Date: Jan. 10, 2002

(54) SEMICONDUCTOR CHIP PACKAGE AND METHOD FOR FABRICATING THE SAME

(76) Inventors: JAE-HONG KIM, CHUNGCHEONGNAM-DO (KR); SI-CHAN SUNG, CHUNGCHEONGNAM-DO (KR)

Correspondence Address: SKJERVEN MORRILL MACPHERSON LLP, 25 METRO DRIVE, SUITE 700, SAN JOSE, CA, 95110, US

(21) Appl. No.: 09/310,466

(22) Filed: May 12, 1999

(30) Foreign Application Priority Data
May 13, 1998 (KR) 1998-17262

(51) Int. Cl. H01L 23/48; H01L 23/52

(52) U.S. Cl. 257/778

(57) ABSTRACT

A semiconductor package includes: a substrate having conductive lead patterns formed on a bottom surface of the substrate; a semiconductor chip electrically connected to the substrate by bonding wires or bumps and flip-chip bonding; and an encapsulating body that encapsulates the semiconductor chip. The semiconductor package can further include a deformation preventing pattern that is under the semiconductor chip to reduce warpage of the package. In accordance with another embodiment of the invention, a method for forming the semiconductor package includes: preparing the substrate; electrically connecting the chip to the conductive pattern; and encapsulating semiconductor chip. The packages and manufacturing methods in accordance with the present invention employ common packaging components and processes to avoid the extra cost and difficulties associated with conventional fine-pitch plastic packages.

### BACKGROUND OF THE INVENTION

1. Field of the Invention

The present invention relates to a semiconductor chip package and a method for fabricating the same, and more particularly to a chip scale package and a method for fabricating the same.

2. Description of the Related Art

As semiconductor integrated circuit chips become more multi-functional and highly integrated, the chips include more bonding pads (or terminal pads), and thus packages for the chips have more external terminals (or leads). When a conventional plastic package that has its leads along the perimeter of the package must accommodate a large number of leads, the footprint of the package increases. However, a goal in many electronic systems is to minimize the size of the systems. Thus, to accommodate a large number of pins without increasing the footprint of package, pin pitch (or lead pitch) of the package must decrease. However, a pin pitch of less than about 0.4 mm gives rise to many technical concerns. For example, trimming of a package having a pin pitch less than 0.4 mm requires expensive trimming tools, and the leads are prone to bending during handling of the package. In addition, surface-mounting of such packages demands a costly and complicated surface-mounting process.

To avoid the technical problems of conventional fine-pitch packages, packages that have area array external terminals have been suggested. Among these packages are ball grid array packages and chip scale packages, which can be considered miniaturized versions of the ball grid array packages. The semiconductor industry presently uses a number of chip scale packages. A micro ball grid array package (μBGA) and a bump chip carrier (BCC) are examples of the chip scale packages. The μBGA package includes a polyimide tape on which a conductive pattern is formed and employs a totally different manufacturing process from a conventional plastic packaging. The bump chip carrier package includes a substrate having grooves formed around a central portion of a top surface of a copper alloy plate and an electroplating layer formed in the grooves. Accordingly, chip scale packages use specialized packaging materials and processes that increase package manufacturing costs.

Therefore, a chip scale package that uses conventional packaging materials and processes is needed for a cost-effective package with a small footprint.

### SUMMARY OF THE INVENTION

According to an embodiment of the present invention, a semiconductor package includes: a substrate having a conductive lead pattern formed on a bottom surface of the substrate and holes open to a top surface of the substrate so as to expose part of the conductive lead pattern; a semiconductor chip attached to the top surface of the substrate; bonding wires electrically connecting bonding pads of the chip to the corresponding exposed conductive lead pattern; and an encapsulating body which encapsulates the semiconductor chip and the bonding wires. The conductive lead pattern is used as external terminals of the package, and additional conductive means such as solder balls can be attached to the conductive patterns to facilitate surface-mounting of the package.

The semiconductor package can further include a deformation preventing pattern to reduce warpage of the package. The deformation preventing pattern can be made of the same material as the conductive pattern, or can be made of an insulating material.

Instead of the bonding wires, conductive bumps can be formed on the bonding pads of the chip, so that the chip is flip-bonded to the exposed conductive pattern. In addition, a plated layer may be formed on the conductive lead pattern.

In accordance with another embodiment of the invention, a method for forming the semiconductor package described above includes: preparing the substrate; attaching a semiconductor chip to the top surface of the substrate with an adhesive; electrically connecting the bonding pads of the chip to the corresponding exposed conductive pattern; and encapsulating semiconductor chip and any bonding wires or conductive bumps.

### BRIEF DESCRIPTION OF THE DRAWINGS

Features and advantages of the present invention will become apparent by describing in detail specific embodiments thereof with reference to the accompanying drawings, in which:

FIG. 1 is a partial cut-away perspective view of a semiconductor package according to an embodiment of the present invention;

FIG. 2 is a bottom view of the semiconductor package of FIG. 1;

FIG. 3 is a sectional view of the semiconductor package of FIG. 1, taken along the line I-I;

FIG. 4 is a sectional view of another semiconductor package according to the invention;

FIG. 5a is a bottom view of a semiconductor package having the cross-section of FIG. 4;

FIG. 5b is a bottom view of another semiconductor package having the cross-section of FIG. 4;

FIG. 6 is a sectional view of another semiconductor package according to the invention;

FIG. 7 is a bottom view of the semiconductor package of FIG. 6;

FIG. 8 is a sectional view of another semiconductor package according to the invention;

FIGS. 9 to 12 are sectional views of semiconductor packages that according to the invention use conductive bumps instead of bonding wires;

FIG. 13 is a flow diagram of a method for fabricating a semiconductor chip package according to an embodiment of the present invention; and

FIG. 14 is a flow diagram of a method for fabricating a semiconductor chip package according to another embodiment of the present invention.

### DETAILED DESCRIPTION OF THE PREFERRED EMBODIMENTS

Referring to FIGS. 1 to 3, which illustrate a semiconductor package according to an embodiment of the present invention, a semiconductor chip 1 is attached by an adhesive 3 on a top surface of a substrate 10. Substrate 10 includes an insulating sheet 11 and a conductive lead pattern 13 formed under insulating sheet 11. Insulating sheet 11 can be made of a printed circuit board material such as polyimide or FR-5 epoxy, and a silver (Ag) epoxy can be employed as adhesive 3, which attaches chip 1 to insulating sheet 11. Holes 12 formed through insulating sheet 11 are around the perimeter of chip 1 and expose part of conductive lead pattern 13. Metal wires 5 electrically connect bonding pads 2 of chip 1 to the exposed parts of conductive lead pattern 13. Finally, a mold body 7, which is typically made of a molding compound, encapsulates chip 1 and metal wires 5.

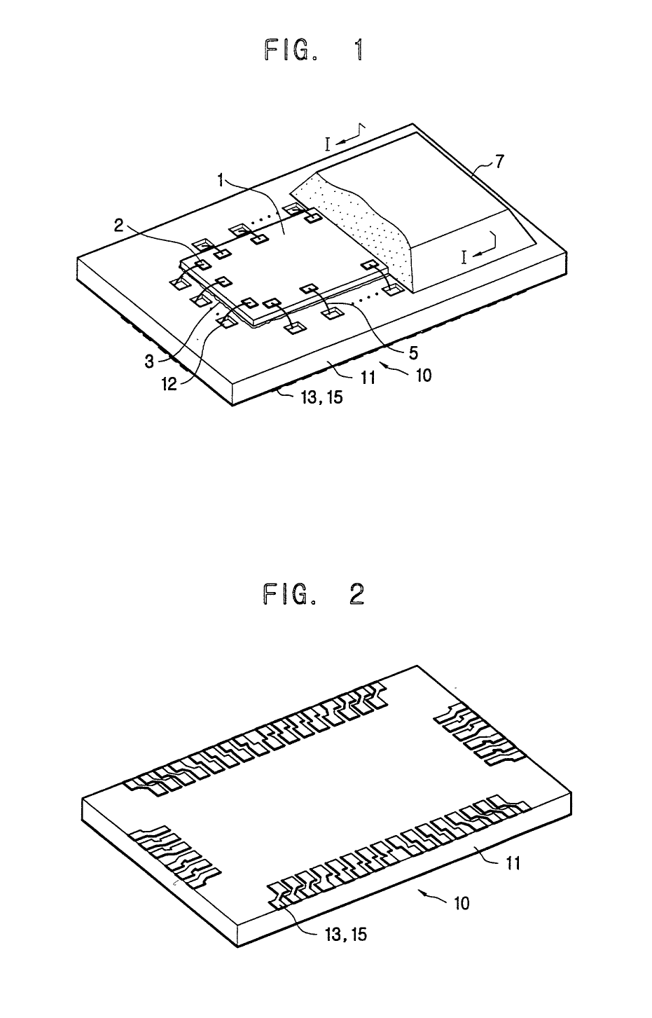

To prevent oxidation of conductive lead pattern 13 and facilitate soldering of the semiconductor package to a mother board, a plated layer 15 can be formed on conductive lead pattern 13. Plated layer 15 can be formed of tin, solder alloys or gold. In addition, being external terminals of the semiconductor package, conductive lead pattern 13 is patterned so as to accommodate various surface-mounting technologies. In FIG. 2, conductive lead pattern 13 extends to edges of insulating sheet 11 for edge soldering.

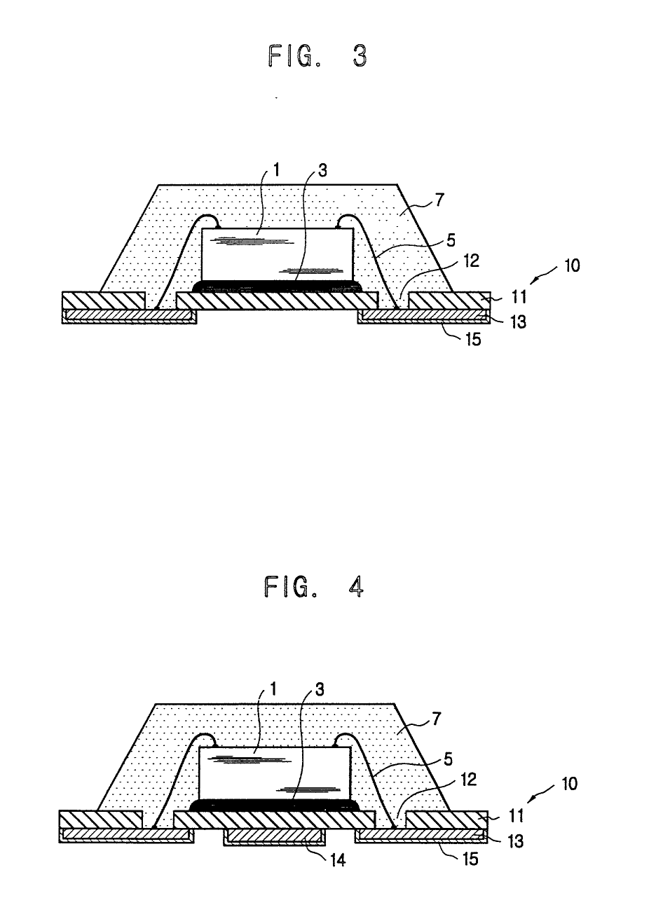

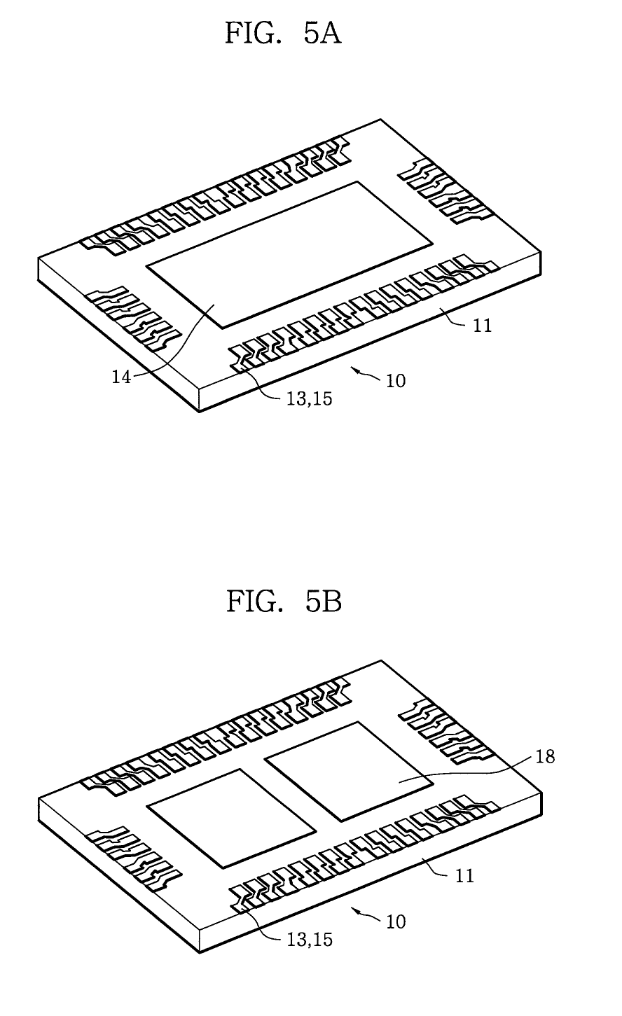

The semiconductor package of FIG. 2 includes no pattern on a center portion of a bottom surface of insulating sheet 11. When chip 1 is attached to insulating sheet 11, the center portion can be deformed or warped due to a difference between the thermal expansion coefficients of chip 1 and insulating sheet 11. To make the center portion resistant to the deformation, a deformation preventing pattern can be formed on the bottom surface of insulating sheet 11 as shown in FIGS. 4, 5A and 5B. FIGS. 5A and 5B respectively show a single deformation preventing pattern 14 and a divided deformation preventing pattern 18 formed at the center portion of the bottom surface of insulating sheet 11. Deformation preventing patterns 14 and 18 can be made of the same material as conductive lead pattern 13 or of an insulating material, and are electrically separate from conductive lead pattern 13.

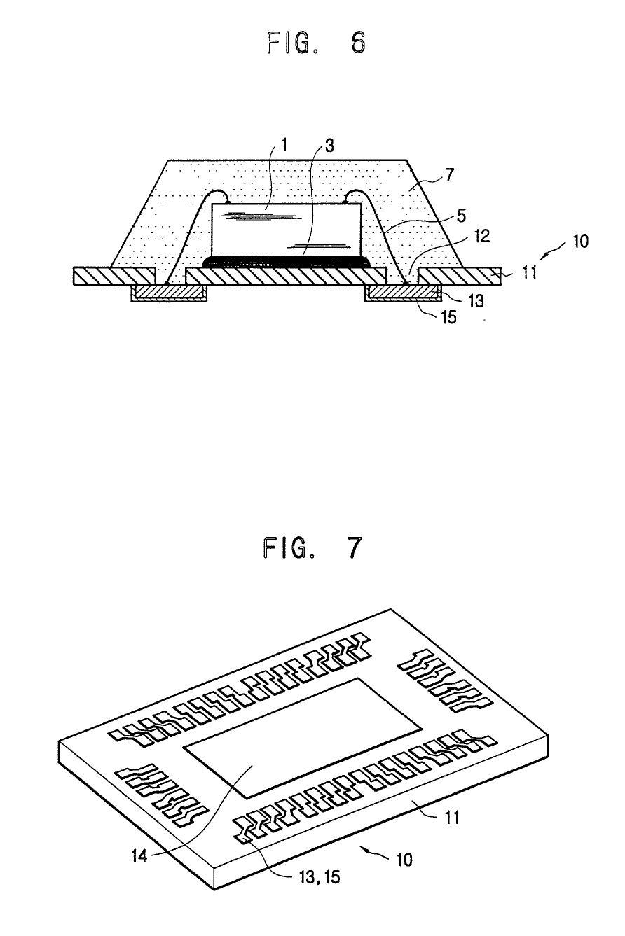

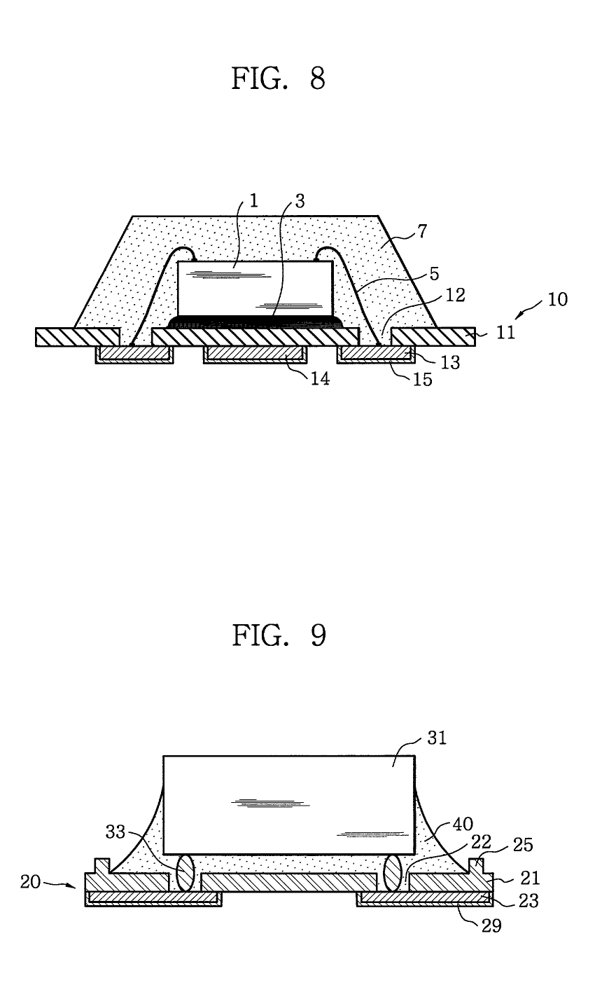

FIGS. 6 to 8 show semiconductor packages having conductive lead patterns 13 that do not extend to the edges of the packages. The package of FIG. 6 does not include a deformation preventing pattern, while the packages of FIGS. 7 and 8 include a deformation preventing pattern 14.

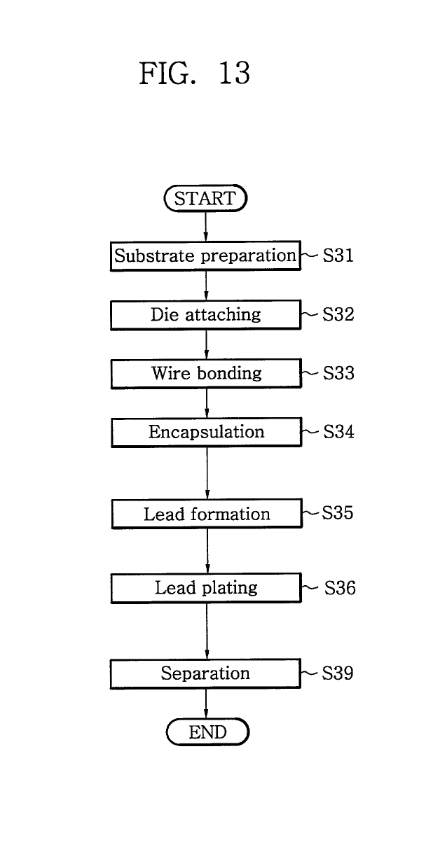

Referring to FIG. 13, two methods of manufacturing the semiconductor packages of FIGS. 1 to 8 in accordance with the present invention can be explained. One method starts with step 31 by preparing a substrate that includes an insulating sheet having throughholes formed along a perimeter of one or more central areas for mounting of one or more chips. A large base substrate having multiple unit substrates, each unit substrate having a central area for a chip, can be used to improve efficiency of a packaging process. A conductive plate attaches to a bottom side of the insulating sheet.

Step 32 attaches one or more semiconductor chips to the insulating sheet with an adhesive. In step 33, a conventional wirebonding connects bonding pads of each semiconductor chip to the conductive plate where exposed through the throughholes; and a transfer-molding or dispensing of step 34 encapsulates each semiconductor chip and its associated wirebonding area.

After step 34, a conventional etching process patterns the conductive plate to form a conductive lead patterns which form the external terminals of each semiconductor package and if necessary, deformation preventing patterns (step 35). Step 36 plates the conductive lead pattern with tin, solder alloys or gold using a plating technique such as electroplating. The deformation preventing pattern can be formed in an extra step after step 36 by attaching pieces of insulating material to the bottom surface of the substrate. Finally, when a number of semiconductor packages are manufactured on a large base substrate having multiple unit substrates, step 39 separates the base substrate to form individual semiconductor packages.

The other method of FIG. 13 eliminates steps 35 and 36. Instead, step 31 prepares a substrate that includes an insulating sheet and a conductive lead pattern formed on a bottom surface of the insulating sheet. Selectively etching a conductive sheet attached to the bottom surface of the insulating film can prepare such a substrate. If necessary, the conductive lead pattern is plated with tin, solder alloys or gold. In addition, a deformation preventing pattern can be formed on the bottom surface of the insulating film by the etching or attaching a piece of insulating sheet. Steps 34, 33, 34 and 39 are the same in both methods.

FIGS. 9 to 12 show semiconductor packages, which employ flip-chip bonding to connect semiconductor chips to external terminals of the packages, in accordance with other embodiments of the present invention.

Referring to FIGS. 9 to 12, a semiconductor chip 31 having conductive bumps 33 formed on bonding pads of semiconductor chip 31 electrically connects to a substrate 20 which includes an insulating sheet 21 and a conductive lead pattern 23 formed under insulating sheet 21. Insulating sheet 21 has holes 22 formed therethrough along a perimeter of chip 31, and a part of conductive lead pattern 23 is exposed through throughholes 22. Conductive bumps 33 connect to the exposed part of conductive lead pattern 23 by a flip-chip bonding. Then, an encapsulating body 40 is formed between chip 31 and substrate 20 to protect the flip-chip bonding area. Encapsulating body 40 is typically formed by dispensing a liquid encapsulant (underfill material), and thus, in order to prevent an overflow of the encapsulant, substrate 20 may include a dam 25 formed on a top surface thereof. Insulating sheet 21 can be made of a printed circuit board material such as polyimide or FR-5 epoxy, and conductive bumps 33 can be made of solder alloys.

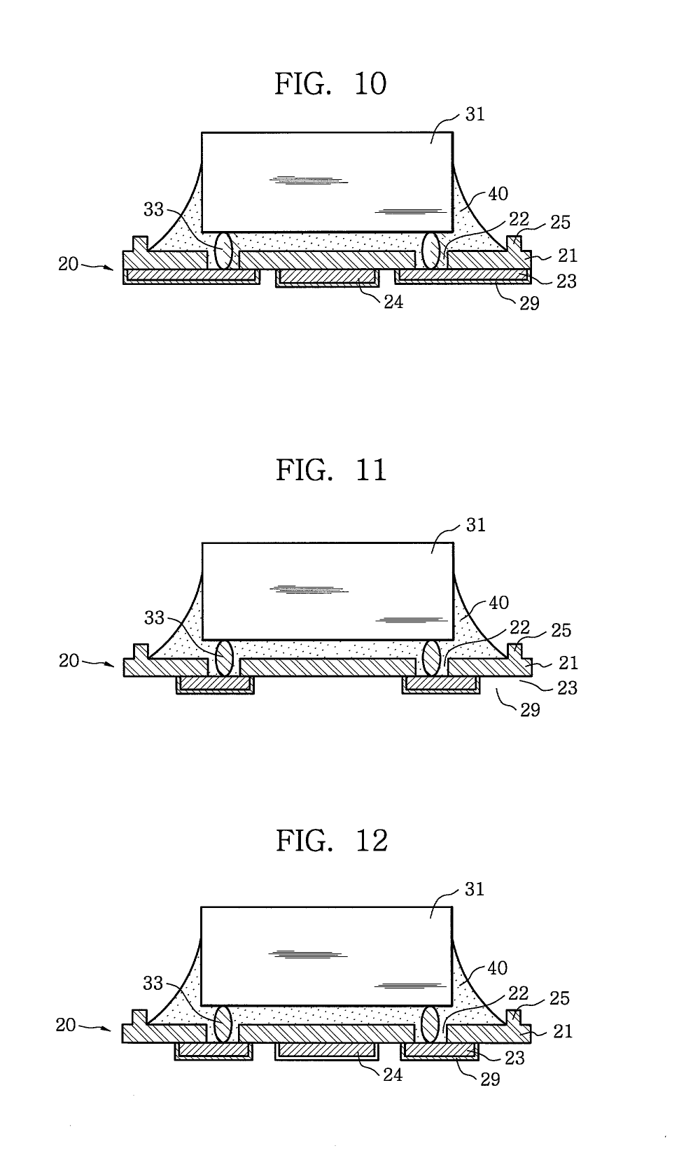

To prevent oxidation of conductive lead pattern 23 and to obtain an easy soldering of the semiconductor package to a mother board, an electroplating layer 29 can be formed on conductive lead pattern 23. Electroplating layer 29 can be formed of tin, solder alloys or gold. In addition, being external terminals of the semiconductor package, conductive lead pattern 23 is patterned so as to accommodate various surface-mounting technologies. In FIGS. 9 and 10, conductive lead pattern 23 extends to edges of insulating sheet 21 for edge soldering.

The semiconductor package of FIG. 9 includes no pattern on a center portion of a bottom surface of insulating sheet 21. When chip 31 is flip-chip bonded to insulating sheet 11, the center portion can be deformed or warped due to a difference between the thermal expansion coefficients of chip 31 and insulating sheet 21. Thus, to make the center portion resistant to the deformation, a deformation preventing pattern 24 can be formed on the bottom surface of insulating sheet 21 as shown in FIGS. 10 and 12. Deformation preventing patterns 24 can be made of the same material as conductive lead pattern 13 or an insulating sheet material, and is electrically insulated from conductive lead pattern 13. FIGS. 11 and 12 show semiconductor packages having their conductive lead patterns 23 not extending to the edges of the packages.

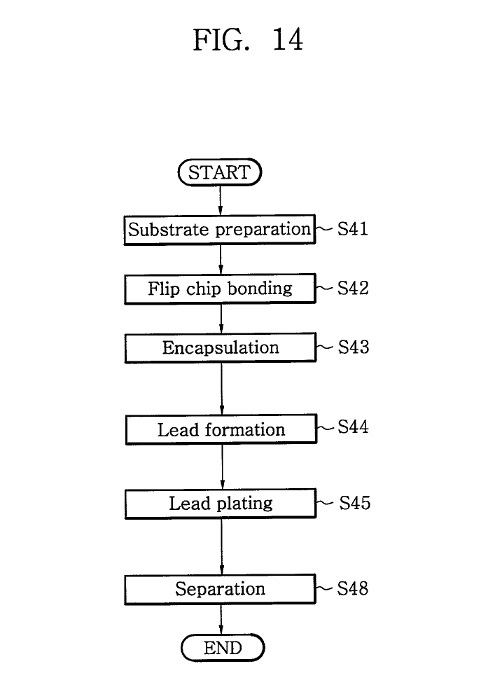

Referring to FIG. 14, two methods of manufacturing the semiconductor packages of FIGS. 9 to 12 in accordance with the present invention can be explained. One method starts with step 41 by preparing a substrate. The substrate includes an insulating sheet having throughholes formed to receive conductive bumps of a semiconductor chip. A conductive plate attaches to the bottom of the insulating sheet. In step 42, a flip chip bonding bonds the conductive bumps formed on bonding pads of the semiconductor chip to the portions of the conductive plate exposed through the throughholes; and a dispensing method of step 43 encapsulates the flip-chip bonding area between the chip and the substrate.

After step 43, a conventional etching process of step 44 patterns the conductive plate to form a conductive lead pattern which is used as external terminals of the semiconductor package and if necessary, a deformation preventing pattern. Step 45 plates the conductive lead pattern with tin, solder alloys or gold. The deformation preventing pattern can be formed in an optional step after step 45 by attaching a piece of an insulating sheet to the bottom surface of the substrate. Finally, when a number of semiconductor packages are manufactured on a large base substrate having multiple unit substrates, step 48 separates the base substrate into individual semiconductor packages.

The alternative method of FIG. 14 eliminates steps 44 and 45. Instead, step 41 prepares a substrate that includes an insulating sheet and a conductive lead pattern formed on a bottom surface of the insulating sheet, for example, by selectively etching a conductive sheet attached to the bottom surface of the insulating film. If necessary, the conductive lead pattern is plated with tin, solder alloys or gold. In addition, a deformation preventing pattern can be formed on the bottom surface of the insulating film by the etching or attaching a piece of an insulating sheet. Steps 41, 32, 43 and 48 are the same in both methods.

The constituents and manufacturing methods employed in the semiconductor packages in accordance with the present invention are common in the field of semiconductor chip packaging so that none of extra cost or difficulties that arise in manufacturing of a conventional fine-pitch plastic package occur.

The present invention has been described above with reference to the aforementioned embodiments. It is evident, however, that many alternative modifications and variations will be apparent to those having skill in the art in light of the foregoing description. Accordingly, the present invention embraces all such alternative modifications and variations as fall within the spirit and scope of the invention defined by the appended claims.

What is claimed is:

1. A semiconductor chip package comprising:
a substrate having holes formed therethrough and a conductive lead pattern formed on a bottom surface of said substrate with part of said conductive lead pattern being exposed through said holes;
a semiconductor chip having bonding pads formed on an active surface thereof and placed on a top surface of said substrate;
a connector that electrically connects said bonding pads of said semiconductor chip to said conductive lead pattern exposed through said holes; and
an encapsulating body that encapsulates said semiconductor chip and said connecting means.

2. The package of claim 1, wherein said conductive lead patterns extends to edges of said bottom surface of said substrate.

3. The package of claim 1, further comprising a deformation preventing pattern formed on said bottom surface of said substrate, said deformation preventing pattern being electrically insulated from said conductive lead pattern.

4. The package of claim 3, wherein said deformation preventing pattern is formed of a material used in said conductive lead pattern.

5. The package of claim 3, wherein said deformation preventing pattern is formed of an insulating material.

6. The package of claim 1, wherein a plated layer is formed on said conductive lead pattern.

7. The package of claim 1, wherein said connector comprises conductive wires.

8. The package of claim 1, wherein said connector comprises conductive bumps formed on said bonding pads of said semiconductor chip.

9. The package of claim 8, further comprising a dam on said top surface of said substrate to prevent an overflow of a liquid encapsulant during formation of said encapsulant body.

10. A method for fabricating a semiconductor chip package comprising:
preparing a substrate comprising an insulating sheet having holes formed therethrough, and a conductive sheet attached to a bottom surface of said insulating sheet, said holes exposing parts of said conductive sheet;
electrically connecting a semiconductor chip having bonding pads formed on a surface thereof to said conductive sheet;
encapsulating said semiconductor chip; and
patterning said conductive plate into a conductive lead pattern.

11. The method of claim 10, wherein electrically connecting said semiconductor chip comprises attaching said semiconductor chip on a top surface of said substrate by an adhesive, and connecting conductive wires between said, bonding pads and respective parts of said conductive sheet exposed through said holes.

12. The method of claim 10, wherein electrically connecting said semiconductor chip comprises forming conductive bumps on said bonding pads, and flip-chip bonding of said conductive bumps to respective parts of said conductive sheet exposed through said holes.

13. The method of claim 10, further comprising forming a deformation preventing pattern on said bottom surface of said substrate.

14. The method of claim 13, wherein forming said deformation preventing pattern comprises patterning said conductive plate into said conductive lead pattern and said deformation preventing pattern.

15. The method of claim 13, wherein forming said deformation preventing pattern comprises attaching a piece of insulating sheet to said bottom surface of said substrate.

16. The method of claim 10, further comprising forming a plated layer on said conductive lead pattern

17. A method for fabricating a semiconductor chip package comprising:
preparing a substrate comprising an insulating sheet having holes formed therethrough, and a conductive lead pattern formed on a bottom surface of said insulating sheet, said holes exposing parts of said conductive lead pattern;
electrically connecting a semiconductor chip having bonding pads formed on a surface thereof to said conductive lead pattern; and
encapsulating said semiconductor chip.

18. The method of claim 17, wherein electrically connecting said semiconductor chip comprises attaching said semiconductor chip on a top surface of said substrate with an adhesive, and connecting conductive wires between said bonding pads respective parts of said conductive lead pattern exposed through said holes.

19. The method of claim 17, wherein electrically connecting said semiconductor chip comprises forming conductive bumps on said bonding pads, and flip-chip bonding said conductive bumps to respective parts of said conductive lead pattern exposed through said holes.

20. The method of claim 17, wherein preparing said substrate comprises attaching a conductive sheet to said insulating sheet, and patterning said conductive plate into said conductive lead pattern.

21. The method of claim 20, wherein preparing said substrate further comprises forming a plated layer on said conductive lead pattern

22. The method of claim 20, wherein a deformation preventing pattern is formed on said bottom surface of said substrate when patterning said conductive plate into said conductive lead pattern.

23. The method of claim 17, further comprising attaching a piece of insulating sheet to said bottom surface of said substrate to form a deformation preventing pattern.
